(19) United States
(12) Patent Application Publication
(10) Pub. No.: US 2017/0257128 A1
(43) Pub. Date: Sep. 7, 2017

(54) RECEIVING CIRCUIT

(71) Applicant: KABUSHIKI KAISHA TOSHIBA, Tokyo (JP)

(72) Inventor: Tadashi KANEMARU, Fuchu Tokyo (JP)

(21) Appl. No.: 15/232,581

(22) Filed: Aug. 9, 2016

(30) Foreign Application Priority Data
Mar. 3, 2016 (JP) 2016-041393

(51) Int. Cl. H04B 1/12; H03F 3/00; H03F 1/56

(52) U.S. Cl. CPC H04B 1/12; H03F 1/56; H03F 3/005; H03F 2200/294

(57) ABSTRACT

A receiving circuit includes a plurality of filter circuits connectable between a first terminal and a second terminal. Each of the filter circuits is configured to pass a different frequency band. A first switching portion is configured to selectively connect one of the filter circuits to the first and second terminals. A node is between the first switching portion and the second terminal and a second switching portion is configured to connect the node to one of a plurality of third terminals that respectively corresponds to the plurality of filter circuits.

### CROSS-REFERENCE TO RELATED APPLICATION

This application is based upon and claims the benefit of priority from Japanese Patent Application No. 2016-041393, filed Mar. 3, 2016, the entire contents of which are incorporated herein by reference.

### FIELD

Embodiments described herein relate generally to receiving circuits.

### BACKGROUND

In communication devices, such as a portable electronic device, technologies such as multiband communication, which allows communication to be performed in a plurality of frequency bands, and carrier aggregation are used. However, with recent increases in the number of communication frequency bands, the frequency bands are very close to each other, and there are many transmitted and received signals and harmonics, which can result in interference. As a result, even when a band-pass filter is used, a received signal at a desired frequency cannot be distinguished easily and, even when such a signal is distinguished, the loss in signal strength of the received signal becomes undesirably large. Amplifying the received signal using a low-noise amplifier (LNA) is conceivable, but, when a LNA is provided for each communication frequency band, the size of the communication device becomes large.

### DESCRIPTION OF THE DRAWINGS

FIG. 1 is a block diagram depicting an example of a receiving circuit of a communication device according to a first embodiment.

FIG. 2 is a block diagram depicting an example of a receiving circuit of a communication device according to a second embodiment.

FIG. 3 is a block diagram depicting a first example of a modified configuration of the receiving circuit according to the first embodiment (Modified Example 1).

FIG. 4 is a block diagram depicting a second example of a modified configuration of the receiving circuit according to the first embodiment (Modified Example 2).

### DETAILED DESCRIPTION

In general, according to one embodiment, a receiving circuit comprises a plurality of filter circuits connectable between a first terminal and a second terminal. Each of the plurality of filter circuits is configured to pass a different frequency band. A first switching portion is configured to selectively connect one of the plurality of filter circuits to the first and second terminal. A node is between the first switching portion and the second terminal. A second switching portion is configured to connect the node to one of a plurality of third terminals that respectively correspond to the plurality of filter circuits

### First Embodiment

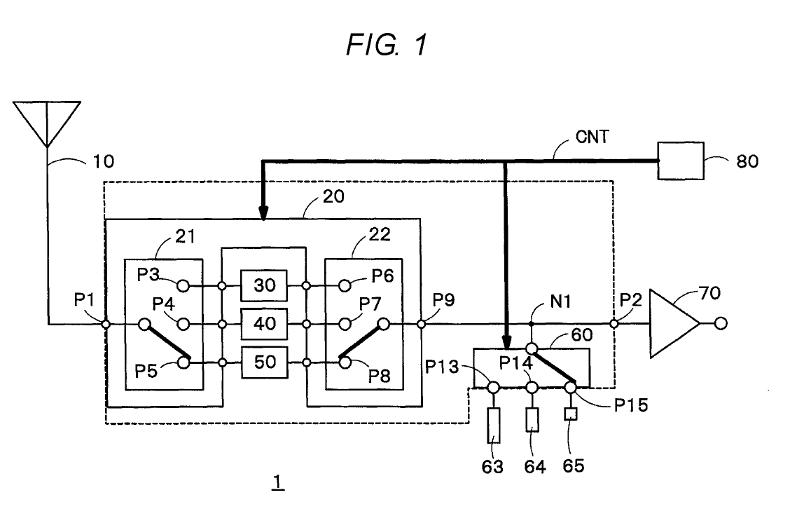

FIG. 1 is a block diagram depicting an example of a receiving circuit 1 of a communication device according to a first embodiment. The communication device may be, for example, a portable communication terminal, such as a smartphone. The receiving circuit 1 receives a high-frequency signal, extracts a signal in a desired frequency band from the high-frequency signal and amplifies the signal, and then provides the amplified signal to a decoder circuit or the like. In order to perform such processing, the receiving circuit 1 includes an antenna 10, a first switching portion 20, filter circuits 30, 40, and 50, a second switching portion 60, a low-noise amplifier 70 (also referred to as LNA 70), and a controller 80.

The antenna 10 is connected to a first terminal P1 of the first switching portion 20 and receives a high-frequency signal. The antenna 10 supplies the received high-frequency signal to the first terminal P1. As a result, the receiving circuit 1 receives the high-frequency signal at the first terminal P1.

The first switching portion 20 is provided between the first terminal P1 and a terminal P9 and includes a switching element 21 and a switching element 22. The switching element 21 is connected between the first terminal P1 and terminals P3, P4, and P5 and selectively connects the first terminal P1 to any one of the terminals P3, P4, and P5. The switching element 22 is connected between the terminal P9 and terminals P6, P7, and P8 and selectively connects the terminal P9 to any one of the terminals P6, P7, and P8. “Connect” as used here means “being connected” for purposes of transmission of or supply of the high-frequency signal.

The terminal P9 is connected to a second terminal P2. As such, the first switching portion 20 connects a filter circuit selected from the plurality of filter circuits 30, 40, and 50 (hereinafter also referred to as a selected filter circuit) between the first terminal P1 and the second terminal P2. The first switching portion 20 may include, for example, a metal oxide semiconductor field-effect transistor (MOSFET).

If the filter circuit 30 is selected, the switching element 21 connects the first terminal P1 to the terminal P3, and the switching element 22 connects the terminal P9 to the terminal P6. As a result, the filter circuit 30 is selectively connected between the first terminal P1 and terminals P2 and P9. If the filter circuit 40 is selected, the switching element 21 connects the first terminal P1 to the terminal P4, and the switching element 22 connects the terminal P9 to the terminal P7. As a result, the filter circuit 40 is selectively connected between the first terminal P1 and terminals P2 and P9. If the filter circuit 50 is selected, the switching element 21 connects the first terminal P1 to the terminal P5, and the switching element 22 connects the terminal P9 to the terminal P8. As a result, the filter circuit 50 is selectively connected between the first terminal P1 and terminals P2 and P9.

The second switching portion 60 is connected to a node N1 between the first switching portion 20 on one side of the node N1, and the second terminal P2 and the LNA 70 on another side of node N1. In order to provide an impedance match therebetween at the node N1, the second switching portion 60 connects a terminal selected from a plurality of terminals P13, P14, and P15 to the node N1. The second switching portion 60 may also include a MOSFET, for example. The terminals P13, P14 and P15 are connected to stub elements 63, 64, and 65, respectively. The stub elements 63, 64, and 65 are impedance matching elements. For example, stub elements 63, 64, and 65 could be transmission lines (microstrip lines) which differ in length, width, or thickness.

At the node N1, the stub elements 63, 64, and 65 are selectively connected as needed to match the impedance of the first switching portion 20 from the node N1 (the output impedance from the first switching portion 20 at terminal P9) to the impedance of the LNA 70 from the node N1 (the input impedance to the second terminal P2). By matching the output impedance from the terminal P9 to the input impedance of the second terminal P2, the high-frequency signal passing through one of the selected filter circuits 30, 40, or 50 can be transmitted to the LNA 70 with low loss.

The first stub element 63 provides an impedance match at the node N1 for the high-frequency signal passing through the filter circuit 30. The second stub element 64 provides an impedance match at the node N1 for the high-frequency signal passing through the filter circuit 40. The third stub element provides an impedance match at the node N1 for the high-frequency signal passing through the filter circuit 50. As described above, the stub elements 63, 64, and 65 are provided to correspond to the filter circuits 30, 40, and 50, respectively, and are set to provide an impedance match for the high-frequency signals passing through the filter circuits 30, 40, and 50, respectively.

Impedance matching at the node N1 makes the output impedance from the first switching portion 20 (the impedance from the terminal P9) nearly equal to the input impedance to the LNA 70 (the impedance to the second terminal P2) at the node N1. That is, the second switching portion 60 and the stub elements 63, 64 and 65 play the role of performing impedance conversion such that, at the node N1, the output impedance from the side where the selected filter circuit 30, 40, or 50 is located becomes nearly equal to the input impedance to the side where the LNA 70 is located.

For example, if the output impedance from the side where the selected filter circuit 30, 40, or 50 is located is X, the input impedance to the side where the LNA 70 is located is Y, and the impedance at the node N1 is Z, the stub elements 63, 64 and 65 are set such that, for the high-frequency signals passing through the filter circuits 30, 40, and 50, respectively, Z becomes an impedance intermediate between X and Y. As a result, a high-frequency signal of a desired frequency can be transmitted to the LNA 70 from the first switching portion 20 with low loss.

The impedance at the node N1 can be set by the lengths, widths, or thicknesses of the stub elements 63, 64, and 65. The lengths, widths, or thicknesses of the stub elements 63, 64, and 65 are set so as to provide an impedance match at the node N1 for the high-frequency signals passing through the filter circuits 30, 40, and 50, respectively, and minimize the passage loss of a high-frequency signal of a desired frequency.

For example, if the filter circuit 30 is selected, the second switching portion 60 selectively connects the node N1 to the terminal P13 in order to connect the first stub element 63 corresponding to the selected filter circuit 30 to the node N1. If the filter circuit 40 is selected, the second switching portion 60 selectively connects the node N1 to the terminal P14 in order to connect the second stub element 64 corresponding to the selected filter circuit 40 to the node N1. Furthermore, if the filter circuit 50 is selected, the second switching portion 60 selectively connects the node N1 to the terminal P15 in order to connect the third stub element 65 corresponding to the selected filter circuit 50 to the node N1. As described above, the second switching portion 60 selectively connects any one of the stub elements 63, 64, and 65 corresponding to the selected filter circuits 30, 40, and 50, respectively, to the node N1. As a result, for the high-frequency signal passing through the selected filter circuit 30, 40, or 50, the impedance to the side where the selected filter circuit 30, 40, or 50 is located from the node N1 can be matched to the impedance to the side where the second terminal P2 and the LNA 70 are located from the node N1.

The LNA 70 is connected to the second terminal P2 and amplifies the high-frequency signal output from the second terminal P2. The LNA 70 outputs the amplified high-frequency signal to a decoder circuit (not depicted in the drawing) or the like which connects to the LNA 70. The LNA 70 may comprise, for example, a field-effect transistor (FET) provided on a silicon substrate or an FET provided on a gallium arsenide (GaAs) substrate.

The controller 80 is connected to the first and second switching portions 20 and 60 and controls the first and second switching portions 20 and 60 by the same control signal CNT. Therefore, the second switching portion 60 selectively connects any one of the stub elements 63, 64, and 65 corresponding to the selected filter circuits 30, 40, and 50, respectively, to the node N1 in synchronization with the operation by which the first switching portion 20 selects the filter circuit 30, 40, or 50. That is, the second switching portion 60 switches one of the stub elements 63, 64, or 65 to be connected to the node N1 in synchronization with the switching of the selected filter circuit 30, 40, or 50, which is performed by the first switching portion 20. In another embodiment, the first and second switching portions 20 and 60 operate in synchronization with each other without being controlled by the same control signal CNT.

In the present embodiment, the first switching portion 20 is a single-pole-3-throw (SP3T)-type switch, but the first switching portion 20 is not limited thereto and may be an mPnT-type switch (m is an integer greater than or equal to 1 and n is an integer greater than or equal to 2). Desirably, n is equal to the number of filter circuits. In the present embodiment, the second switching portion 60 is a single-pole-3-throw (SP3T)-type switch, but the second switching portion 60 is not limited thereto and may be an mPnT-type switch (m is an integer greater than or equal to 1 and n is an integer greater than or equal to 2). In some embodiments, the number of filter circuits is desirably equal to the number of stub elements. Moreover, n is desirably equal to the number of filter circuits and the number of stub elements in some embodiments.

The stub elements 63, 64, and 65 are, for example, transmission lines (microstrip lines) formed of a conductive material such as metal and make the impedances at the node N1 differ from one another by the lengths, widths, and thicknesses thereof. For example, the filter circuit 30 is assumed to selectively allow a high-frequency signal RF_{LB} in a relatively low frequency band (a low band) to pass therethrough, the filter circuit 50 is assumed to selectively allow a high-frequency signal RF_{HB} in a relatively high frequency band (a high band) to pass therethrough, and the filter circuit 40 is assumed to selectively allow a high-frequency signal RF_{MB} in a frequency band (a middle band) intermediate between the relatively low frequency band and the relatively high frequency band to pass therethrough. In the present embodiment, the stub elements 63, 64, and 65 all have almost the same width and thickness, and the impedances of the stub elements 63, 64, and 65 are adjusted by varying the lengths thereof. In this case, the first stub element 63 (corresponding to the filter circuit 30) is formed of a relatively long strip line in accordance with a wavelength λ_{LB} of the high-frequency signal RF_{LB}. The second stub element 64 (corresponding to the filter circuit 40) is formed of a strip line of a middle length in accordance with a wavelength λ_{MB} of the high-frequency signal RF_{MB}. The third stub element 65 (corresponding to the filter circuit 50) is formed of a relatively short strip line in accordance with a wavelength λ_{HB} of the high-frequency signal RF_{HB}. Assuming the lengths of the stub elements 63, 64, and 65 are SL_{LB}, SL_{MB}, and SL_{HB}, respectively, the following Expressions 1, 2, and 3 are true:

λ_{LB}/λ_{MB}˜SL_{LB}/SL_{MB} (Expression 1)

λ_{MB}/λ_{HB}˜SL_{MB}/SL_{HB} (Expression 2)

λ_{HB}/λ_{LB}˜SL_{HB}/SL_{LB} (Expression 3)

As described above, the ratio of the lengths SL_{LB}, SL_{MB}, and SL_{HB} of the stub elements 63, 64, and 65, respectively, is nearly equal to the ratio of the wavelengths λ_{LB}, λ_{MB}, and λ_{HB} of the high-frequency signals passing through the filter circuits 30, 40, and 50 corresponding to the stub elements 63, 64, and 65, respectively. The impedance of the node N1 is adjusted by the overall configuration from the node N1 to the stub element (any one of the stub elements 63, 64, and 65) selected by the second switching portion 60. Therefore, the lengths of the stub elements 63, 64, and 65 are not necessarily set by Expressions 1, 2, and 3, but rather, they are set such that the passage loss (a reduction in the power level) of the high-frequency signal is minimized.

In the present embodiment, one end of each of the stub elements 63, 64, and 65 is connected to a corresponding one of the terminals P13, P14, and P15, and the other end of each of the stub elements 63, 64, and 65 is in an electrically floating state. The other end of each of the stub elements 63, 64, and 65 is in an open state for the high-frequency signal. However, the other end of each of the stub elements 63, 64, and 65 may instead be grounded. In this case, the other end of each of the stub elements 63, 64, and 65 is in a closed (shorted) state for the high-frequency signal. The lengths of the stub elements 63, 64, and 65 which are necessary for providing an impedance match are different in the open state and in the closed state. However, in either the open state or the closed state, by adjusting the lengths of the stub elements 63, 64, and 65, an impedance match can be provided in an appropriate manner. By selecting the open state or the closed state, the lengths of the stub elements 63, 64, and 65 are shortened, and the circuit size of the receiving circuit 1 can be reduced.

In the present embodiment, as indicated by the dashed line of FIG. 1, the first switching portion 20, the filter circuits 30, 40, and 50, and the second switching portion 60 are incorporated into one semiconductor chip. The antenna 10, the LNA 70, the controller 80, and the stub elements 63, 64, and 65 are attached to the semiconductor chip externally. Use of the LNA 70 may not be necessary in some embodiments, and use and/or desired performance of the LNA 70 may be arbitrarily selected. Moreover, when the LNA 70 is used, any one of the stub elements 63, 64, and 65 can be selected, and/or the stub elements 63, 64, and 65 can be adjusted such that the impedance to the first switching portion 20 from the node N1 (the output impedance from the first switching portion 20) is matched to the impedance to the LNA 70 from the node N1 (the input impedance to the LNA 70). That is, one of the stub elements 63, 64, and 65 can be selected in accordance with the selected LNA 70. As described above, by attaching the LNA 70 and the stub elements 63, 64, and 65 to the semiconductor chip externally, the flexibility in selecting the stub elements 63, 64, and 65 is increased. Moreover, by incorporating the first switching portion 20, the filter circuits 30, 40, and 50, and the second switching portion 60 into one semiconductor chip, variations in characteristics of the first switching portion 20 and the second switching portion 60 can be reduced.

As described above, according to the present embodiment, the second switching portion 60 is connected to the node N1 between the first switching portion 20 and the second terminal P2 and connects the stub element 63, 64, or 65 corresponding to the selected filter circuit 30, 40, or 50, respectively, to the node N1. As a result, the receiving circuit 1 can provide an impedance match at the node N1 for the high-frequency signal from the selected filter circuit 30, 40, or 50. Therefore, the receiving circuit 1 can transmit a received signal of a desired frequency to the LNA 70 with low passage loss even after passing this received signal through the selected filter circuit 30, 40, or 50. That is, the receiving circuit 1 can provide a received signal (from antenna 10) at a particular desired frequency to the LNA 70 without significantly reducing the power level of this particular received signal, while also still being able to provide received signals at other frequencies without significantly reducing the power level of these other received signals. As a result, the receiving circuit 1 can have increased reception sensitivity for the high-frequency signal at the desired frequency.

Moreover, the receiving circuit 1 does not require a separate LNA 70 for each of the filter circuits 30, 40, and 50; rather, a common LNA 70 can be used for the plurality of filter circuits 30, 40, and 50. As a result, although the second switching portion 60 and the stub elements 63, 64, and 65 are added, the circuit size of the receiving circuit 1 can be reduced as a whole. For example, when high-frequency signals in many frequency bands are received, n of mPnT becomes large and the number of filter circuits is increased. In such a case, the circuit size of the receiving circuit 1 according to the present embodiment is reduced as compared to a device in which a separate LNA 70 would have to be provided for each filter circuit, whereby the size of the communication device is reducible.

In the example described above, the impedance is adjusted by adjusting lengths of the stub elements 63, 64, and 65. However, the impedance may also be adjusted by adjusting one or more of the lengths, widths, and thicknesses of the stub elements 63, 64, and 65.

### Second Embodiment

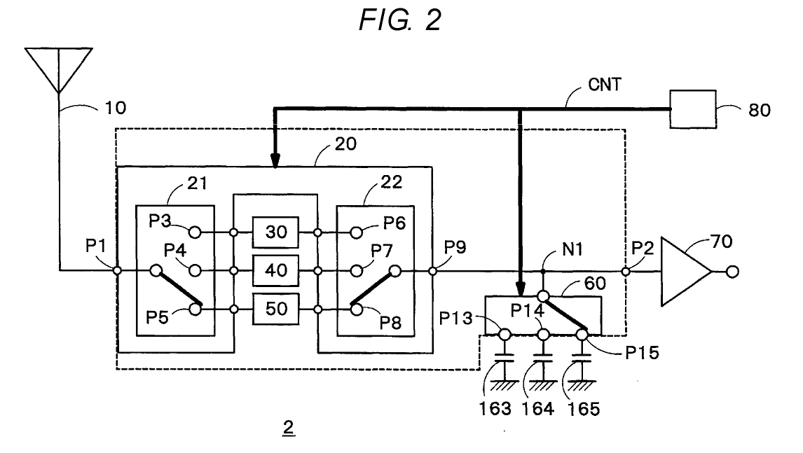

FIG. 2 is a block diagram depicting an example of a receiving circuit 2 of a communication device according to a second embodiment. The receiving circuit 2 according to the second embodiment includes capacitance elements 163, 164, and 165 as impedance matching elements. The terminals P13, P14, and P15 are respectively connected to the capacitance elements 163, 164, and 165 serving as the impedance matching elements.

The first capacitance element 163 provides an impedance match between the first switching portion 20 and the LNA 70 connected to the second terminal P2 for the high-frequency signal passing through the filter circuit 30. The second capacitance element 164 provides an impedance match between the first switching portion 20 and the LNA 70 connected to the second terminal P2 for the high-frequency signal passing through the filter circuit 40. The third capacitance element 165 provides an impedance match between the first switching portion 20 and the LNA 70 connected to the second terminal P2 for the high-frequency signal passing through the filter circuit 50.

For example, if the filter circuit 30 is selected, the second switching portion 60 selectively connects node N1 to the terminal P13 to connect the first capacitance element 163 to the node N1. If the filter circuit 40 is selected, the second switching portion 60 selectively connects node N1 to the terminal P14 to connect the second capacitance element 164 to the node N1. Furthermore, if the filter circuit 50 is selected, the second switching portion 60 selectively connects node N1 to the terminal P15 to connect the third capacitance element 165 to the node N1. As described above, the second switching portion 60 selectively connects any one of the capacitance elements 163, 164, and 165 corresponding to the selected filter circuits 30, 40, and 50, respectively, to the node N1. As a result, for the high-frequency signal passing through the selected filter circuit 30, 40, or 50, the impedance to the side where the selected filter circuit 30, 40, or 50 is located from the node N1 can be matched to the impedance to the side where the second terminal P2 and the LNA 70 are located from the node N1.

The capacitance elements 163, 164, and 165 may be elements which can be produced by a semiconductor process, such as a metal oxide silicon (MOS) capacitor or the like. The impedances at the node N1 are made to differ from one another by selectively connecting the capacitances of the capacitance elements 163, 164, and 165. For example, the filter circuit 30 is assumed to selectively allow a high-frequency signal RF_{LB} in a relatively low frequency band to pass therethrough, the filter circuit 50 is assumed to selectively allow a high-frequency signal RF_{HB} in a relatively high frequency band to pass therethrough, and the filter circuit 40 is assumed to selectively allow a high-frequency signal RF_{MB} in a frequency band intermediate between the relatively low frequency band and the relatively high frequency band to pass therethrough. In this case, the first capacitance element 163 has a relatively large capacitance C_{LB} in accordance with a wavelength λ_{LB} of the high-frequency signal RF_{LB}. The second capacitance element 164 has an intermediate capacitance C_{MB} in accordance with a wavelength λ_{MB} of the high-frequency signal RF_{MB}. The third capacitance element 165 has a relatively small capacitance C_{HB} in accordance with a wavelength λ_{HB} of the high-frequency signal RF_{HB}. In one embodiment, for the capacitance elements 163, 164, and 165, the following Expressions 4, 5, and 6 are true:

λ_{LB}/λ_{MB}˜C_{LB}/C_{MB} (Expression 4)

λ_{MB}/λ_{HB}˜C_{MB}/C_{HB} (Expression 5)

λ_{HB}/λ_{LB}˜C_{HB}/C_{LB} (Expression 6)

As described above, the ratio of the capacitances C_{LB}, C_{MB}, and C_{HB} of the capacitance elements 163, 164, and 165 is nearly equal to the ratio of the wavelengths λ_{LB}, λ_{MB}, and λ_{HB} of the high-frequency signals passing through the filter circuits 30, 40, and 50 corresponding to the capacitance elements 163, 164, and 165, respectively. The impedance of node N1 is adjusted by the overall configuration to the capacitance element (any one of the capacitance elements 163, 164, and 165) selected by the second switching portion 60 from the node N1. Therefore, the capacitances of the capacitance elements 163, 164, and 165 are not necessarily set by Expressions 4, 5, and 6, but rather are set such that the passage loss (a reduction in the power level) of the high-frequency signal is minimized.

The remaining configuration of the second embodiment may be the same as the corresponding configuration of the first embodiment. As a result, the second embodiment can obtain the same effect as the first embodiment.

### Modified Example 1

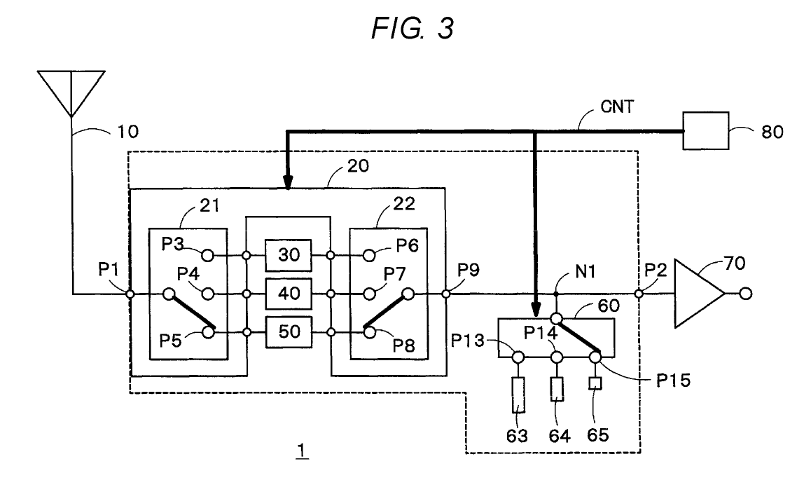

FIG. 3 is a block diagram depicting an example of the configuration of a receiving circuit 1 according to Modified Example 1 of the first embodiment. In this modified example, as indicated by the dashed line of FIG. 3, the filter circuits 30, 40, and 50, the first and second switching portions 20 and 60, and the stub elements 63, 64, and 65 are incorporated into a single semiconductor chip. In this case, since the stub elements 63, 64, and 65 are set in advance, the stub elements 63, 64, and 65 cannot be arbitrarily selected after chip fabrication. However, since the number of parts which are attached to the semiconductor chip externally is reduced, the receiving circuit 1 according to this modified example can be made smaller and variations in the characteristics of the receiving circuit 1 after mounting are curbed. Furthermore, the receiving circuit 1 according to this modified example can also obtain the effect of the first embodiment.

### Modified Example 2

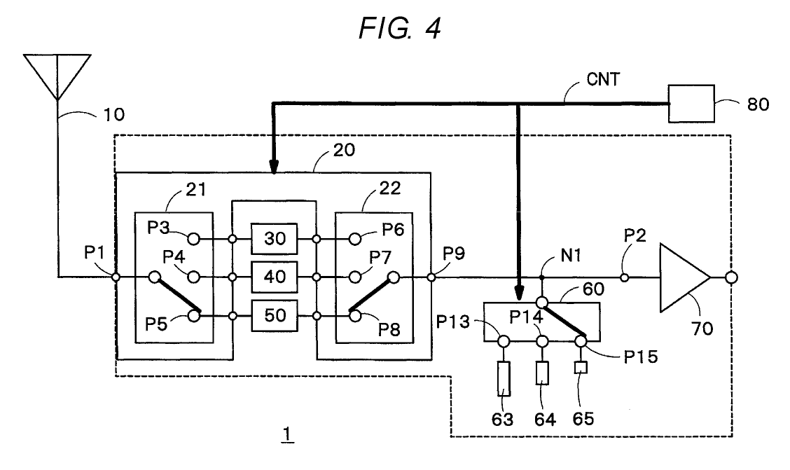

FIG. 4 is a block diagram depicting an example of the configuration of a receiving circuit 1 according to Modified Example 2 of the first embodiment. In this modified example, as indicated by the dashed line of FIG. 4, the filter circuits 30, 40, and 50, the first and second switching portions 20 and 60, the stub elements 63, 64, and 65, and the LNA 70 are incorporated into a single semiconductor chip. In this case, since the stub elements 63, 64, and 65 and the LNA 70 are set in advance, the flexibility in selecting performance is reduced. However, the stub elements 63, 64, and 65 and the LNA 70 are set in advance such that the output impedance from the first switching portion 20 is matched to the input impedance to the LNA 70 at the node N1. As a result, the stub elements 63, 64, and 65 do not have to be matched with the LNA 70 after fabrication. Moreover, since the number of other required parts in addition to the semiconductor chip is reduced, the circuit size of the receiving circuit 1 is reduced and variations in the characteristics of the receiving circuit 1 after mounting are curbed. Furthermore, the receiving circuit 1 according to this modified example also has the effect of the first embodiment.

Modified Examples 1 and 2 described above can also be applied to the second embodiment. As a result, Modified Examples 1 and 2 described above can also obtain the effect of the second embodiment.

While certain embodiments have been described, these embodiments have been presented byway of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A receiving circuit, comprising:
a plurality of filter circuits connectable between a first terminal and a second terminal, each of the plurality of filter circuits configured to pass a different frequency band;
a first switching portion configured to selectively connect one of the plurality of filter circuits to the first and second terminals;
a node between the first switching portion and the second terminal;
a second switching portion configured to connect the node to one of a plurality of third terminals respectively corresponding to the plurality of filter circuits; and
a plurality of impedance matching elements each respectively connected to a corresponding one of the plurality of third terminals, wherein
the impedance matching elements provide an impedance match between an output impedance of the first switching portion and an input impedance of the second terminal, and
each of the plurality of impedance matching elements is a transmission line having at least one of a length, width, or thickness that is different from that of the other transmission lines.

2.-5. (canceled)

6. The receiving circuit according to claim 1, further comprising an amplifier connected to the second terminal.

7. The receiving circuit according to claim 6, wherein the amplifier is integrated on a same semiconductor substrate as the first and second switching portions.

8. The receiving circuit according to claim 1, wherein the first switching portion is configured to connect a selected one of the plurality of filter circuits to the first and second terminals at the same time the second switching portion connects the node to the one of the plurality of third terminals corresponding to the selected one of the plurality of filter circuits.

9. The receiving circuit according to claim 1, wherein the first and second switching portions are controlled by a same control signal.

10. A receiving circuit, comprising:
a plurality of filter circuits each configured to pass a signal in a different frequency band;
a first switching portion between a first terminal and a second terminal and configured to selectively connect one of the plurality of filter circuits between the first and second terminals;
a plurality of impedance matching elements each respectively corresponding to one of the plurality of filter circuits; and
a second switching portion configured to connect one of the plurality of impedance matching elements to a node between the first switching portion and the second terminal according to a selected one of the plurality of filter circuits, wherein
each of the plurality of impedance matching elements is a transmission line having at least one of a length, width, or thickness that is different from that of the other transmission lines.

11. The receiving circuit according to claim 10, wherein the plurality of impedance matching elements provide an impedance match between an output impedance from the first switching portion and an input impedance to the second terminal.

12. The receiving circuit according to claim 10, further comprising an amplifier connected to the second terminal.

13. The receiving circuit according to claim 10, wherein the first switching portion is configured to connect a selected one of the plurality of filter circuits to the first and second terminals at the same time the second switching portion is configured to connect the node to one of the plurality of impedance matching elements corresponding to the selected one of the plurality of filter circuits.

14. The receiving circuit according to claim 10, wherein the first and second switching portions are controlled by a same control signal.

15. (canceled)

16. (canceled)

17. The receiving circuit according to claim 10, wherein a total number of impedance matching elements equals a total number of filter circuits.

18. A semiconductor device, comprising:
a plurality of filter circuits connectable between a first terminal and a second terminal;
a first switching portion between the first terminal and the second terminal configured to selectively connect one of the plurality of filter circuits to the first and second terminals;
a second switching portion configured to connect a node between the first switching portion and the second terminal configured to one of a plurality of third terminals that corresponds to the plurality of filter circuits; and
a plurality of impedance matching elements connected to the plurality of third terminals and corresponding to the plurality of filter circuits, wherein
each of the plurality of impedance matching elements is a transmission line having at least one of a length, width, or thickness that is different from that of the other transmission lines.

19. (canceled)

20. The semiconductor chip according to claim 18, further comprising an amplifier connected to the second terminal.

21. The receiving circuit according to claim 18, wherein the plurality of impedance matching elements includes a first transmission line having a first length, a second transmission line having a second length longer than the first length, and a third transmission line having a third length longer than the second length.

22. The receiving circuit according to claim 21, wherein a ratio of the first length to the second length is equal to a ratio of wavelengths of respective signals to pass through the filter circuits connected to the first transmission line and the second transmission line, and a ratio of the second length to the third length is equal to a ratio of wavelengths of respective signals to pass through the filter circuits connected to the second transmission line and the third transmission line.

23. The receiving circuit according to claim 1, wherein the plurality of impedance matching elements includes a first transmission line having a first length, a second transmission line having a second length longer than the first length, and a third transmission line having a third length longer than the second length.

24. The receiving circuit according to claim 23, wherein a ratio of the first length to the second length is equal to a ratio of wavelengths of respective signals to pass through the filter circuits connected to the first transmission line and the second transmission line, and a ratio of the second length to the third length is equal to a ratio of wavelengths of respective signals to pass through the filter circuits connected to the second transmission line and the third transmission line.

25. The receiving circuit according to claim 10, wherein the plurality of impedance matching elements includes a first transmission line having a first length, a second transmission line having a second length longer than the first length, and a third transmission line having a third length longer than the second length.

26. The receiving circuit according to claim 25, wherein a ratio of the first length to the second length is equal to a ratio of wavelengths of respective signals to pass through the filter circuits connected to the first transmission line and the second transmission line, and a ratio of the second length to the third length is equal to a ratio of wavelengths of respective signals to pass through the filter circuits connected to the second transmission line and the third transmission line.
